(19) United States
(12) Patent Application Publication
(10) Pub. No.: US 2002/0146914 A1
(43) Pub. Date: Oct. 10, 2002

(54) In-situ steam generation process for nitrided oxide

(76) Inventors: Kuo-Tai Huang, Hsin-Chu City (TW); Juan-Yuan Wu, Hsin-Chu City (TW)

Correspondence Address: POWELL, GOLDSTEIN, FRAZER & MURPHY LLP, P.O. BOX 97223, WASHINGTON, DC, 20090-7223, US

(21) Appl. No.: 09/828,657

(22) Filed: Apr. 6, 2001

(51) Int. Cl. H01L 21/31; H01L 21/469

(52) U.S. Cl. 438/769; 438/791; 438/786

(57) ABSTRACT

A N₂O in-situ steam generation (N₂O-ISSG) process for forming an ultra-thin nitrided oxide layer is provided. The N₂O-ISSG process includes placing a silicon substrate in a process chamber, and then introducing a gas mixture comprising N₂O and H₂ into the process chamber at a pressure lower than 10 torr. Thereafter, heating the surface of the silicon substrate to a predetermined temperature about 800˜1100° C. to cause growth of a nitrided silicon dioxide layer on the heated surface of the silicon substrate. The nitrided silicon dioxide layer has nitrogen with a content about 1˜5 atomic %.

### BACKGROUND OF THE INVENTION

1. Field of the Invention

The present invention relates to a process for forming dielectric layers for use in semiconductor devices; and more particularly to nitrogen-contained silicon dioxide dielectric layers.

2. Description of the Prior Art

The trend in integrated circuits is toward higher performance, higher speed, and lower cost. Correspondingly, device dimensions and feature sizes are shrinking for all types of integrated circuit technology. The trend necessitates the use of ultra-thin dielectrics in the fabrication of such devices as metal-oxide-semiconductor (MOS) transistors.

MOS transistors are comprised of highly doped source and drain regions in a silicon substrate, and a conducting gate electrode is situated between the source and drain but separated from the substrate by a thin gate dielectric layer. When an appropriate voltage is applied to the gate electrode, a conducting channel is created between the source and drain. Shorter channels, shallower source and drain junctions, and thinner gate dielectrics are critical to achieve smaller and faster MOS devices.

Ultra-thin dielectrics less than 100 angstroms thick, until less than 15 angstroms for 0.1 um generation, usually of high quality SiO₂, are utilized as MOS gate dielectrics, commonly called gate oxides. While, for the same gate oxide material, several quantum effects, such as boron penetration and hot carrier effect, could happen when the thickness of the gate oxide is shrunk from several hundreds angstroms to several tens angstroms. For ultra-thin gate oxide, boron from the doped polysilicon gate can diffuse completely through the gate oxide into the underlying substrate, causing even more severe threshold shift problem. The hot electrons generated near the drain region, due to the hot carrier effect, also easily inject into the ultra-thin gate oxide, resulting in damage to the gate oxide and/or the Si—SiO₂ interface. And, reliability and reproducibility of the ultra-thin gate oxide is adversely affected by these factors including poor interface structure, high defect density, lacking of thickness control and impurity diffusion through the gate oxide. Theses factors also can seriously degrade device performance.

Incorporation of nitrogen into the ultra-thin gate oxide has been shown to inhibit boron penetration and to improve the Si—SiO₂ interfacial structure. And, ultra-thin oxide (12˜20 angstroms) quality control and method to incorporate nitrogen are the keys to enable scaling oxide application extended to 0.1 um generation. The conventional in-situ steam generation (ISSG) oxide shows excellent oxide quality. However, for forming an ultra-thin gate oxide layer with a thickness about 15 angstroms, at the temperature of about 900° C., the total reaction time of the conventional ISSG process is about 10 seconds. The reaction for the conventional ISSG process occurs rapidly, so that the thickness control (less than 15 angstroms) is difficult. Moreover, the conventional ISSG process produces pure ultra-thin gate oxide, which could not block boron penetration and the hot electrons injecting into the gate oxide. Therefore, the conventional ISSG process could not provide an ultra-thin gate dielectric with a thickness about 12˜20 angstroms useful in 0.13 um generation or more advanced generation, such as 0.1 um generation.

Accordingly, it is an intention to develop a N₂O in-situ steam generation (N₂O-ISSG) process for forming an ultra-thin gate dielectric layer useful for the advanced generation such as 0.13 um or less.

### SUMMARY OF THE INVENTION

An object of this invention is to provide a N₂O in-situ steam generation (N₂O-ISSG) process for forming an ultra-thin nitrided gate oxide layer. The N₂O-ISSG process utilizes N₂O and H₂ as the reaction gases to form an ultra-thin nitrided gate oxide layer on a silicon substrate. The ultra-thin nitrided gate oxide layer contains nitrogen in the surface region and interface region so as to inhibit boron penetration from the doped polysilicon gate and the hot electrons injecting into the gate oxide layer due to the hot carrier effect.

Another object of this invention is to provide a N₂O in-situ steam generation process utilizing N₂O and H₂ as the reaction gases to form an ultra-thin nitrided gate oxide layer on a silicon substrate. The N₂O-ISSG process can be performed at a higher process temperature, and has a reaction rate lower than the conventional ISSG process. Therefore, the N₂O-ISSG process provides a wider process window than the conventional ISSG process.

In order to achieve the above objects, the present invention provides a N₂O in-situ steam generation (N₂O-ISSG) process for forming an ultra-thin nitrided oxide layer on a silicon substrate, which is to be used as a gate dielectric layer. The N₂O-ISSG process comprises placing the silicon substrate in a process chamber and introducing a gas mixture comprising N₂O and H₂ into the process chamber. Thereafter, heating the surface of the silicon substrate to a predetermined temperature to cause growth of a nitrided silicon dioxide layer on the heated surface of the silicon substrate. The nitrided silicon dioxide layer contains nitrogen in the surface region and the interface region to act as a barrier for inhibiting boron penetration from the doped polysilicon gate and the hot electrons injecting into the ultra-thin gate oxide layer due to the hot carrier effect.

### BRIEF DESCRIPTION OF THE DRAWINGS

The foregoing and other advantages and features of the invention will be apparent from the following more particular description of preferred embodiments of the invention, as illustrated in the accompanying drawings.

FIG. 1 is a schematic cross sectional view of a rapid thermal process chamber for implementing the present invention;

FIG. 2 is a process flow diagram for a preferred embodiment of the invention;

FIG. 3 is a cross sectional view of the preferred nitrided silicon dioxide structure manufactured by the process of FIG. 2;

FIG. 4 is a process flow diagram for another preferred embodiment of the invention; and

FIG. 5 is a diagram showing the relation between nitrogen concentration and the depth of the silicon substrate according to the process of FIG. 4.

### DESCRIPTION OF THE PREFERRED EMBODIMENTS

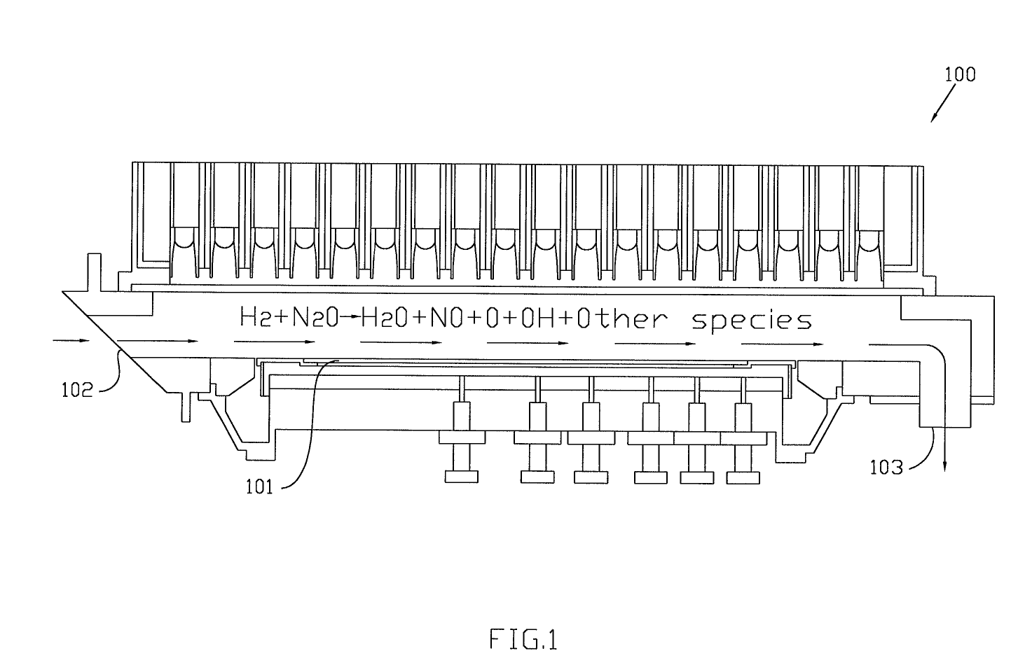

FIG. 1 is a schematic cross sectional view of a rapid thermal process (RTP) chamber 100 for implementing the present invention. A single wafer, for example, a silicon substrate 101, is placed on a supporting plate in the rapid thermal process chamber 100. The reaction gases N₂O and H₂ are introduced into the rapid thermal process chamber 100 from the gas inlet 102. And, the residue gases are pumped out from the gas outlet 103.

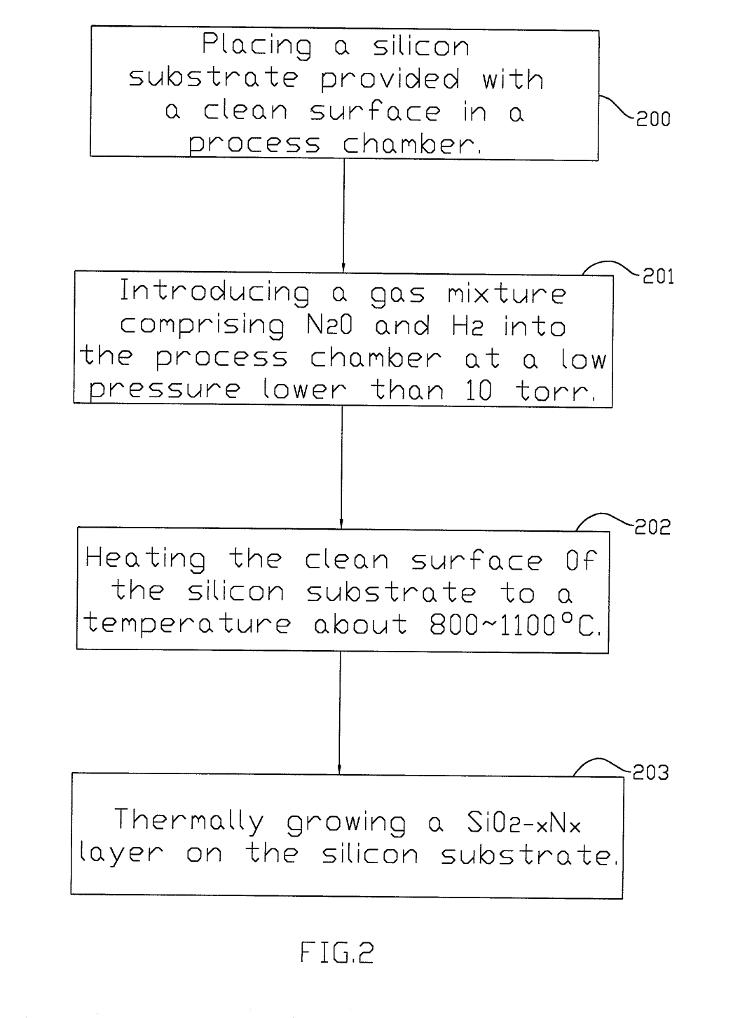

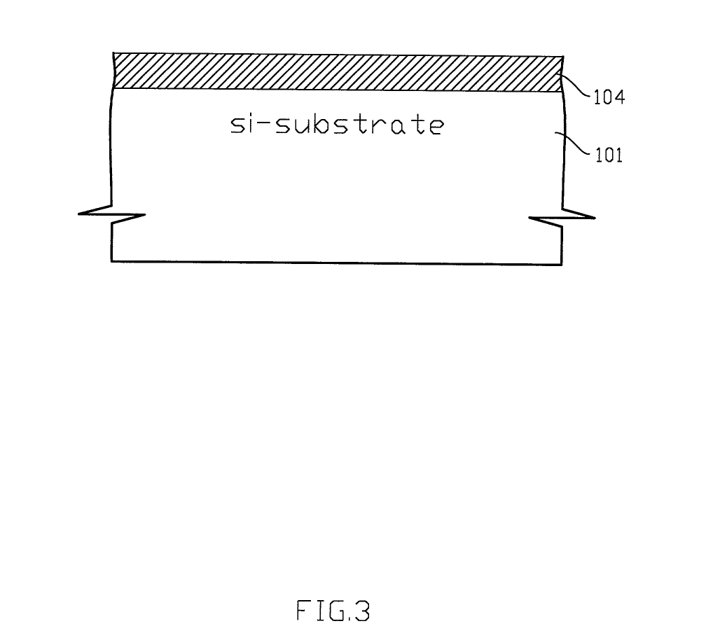

FIG. 2 is a N₂O in-situ steam generation (N₂O-ISSG) process flow according to a preferred embodiment of the invention. In step 200, the silicon substrate 101 provided with a clean surface, is placed in the rapid thermal process chamber 100. In step 201, a gas mixture comprising N₂O and H₂ is introduced into the rapid thermal process chamber 100 at a low pressure lower than 10 torr. The gas mixture consists essentially of N₂O and has a H₂ gas ratio less than 1%. In step 202, heating the clean surface of the silicon substrate 101 to a temperature about 800˜1100° C. In step 203, the heated surface of the silicon substrate 101 initiates the reaction (I) as follows occur to produce atomic oxygen (O) and nitric oxide (NO) radicals at the surface of the silicon substrate 101. Then, as shown in FIG. 3, an oxynitride (SiO₂₋ₓNₓ) layer 104 is formed on the heated surface of the silicon substrate 101, which is used to be a gate dielectric layer. The oxynitride layer 104 is formed mainly by nitric oxide (NO) and atomic oxygen (O). By the present N₂O-ISSG process, for forming an ultra-thin oxynitride layer with a thickness about 15 angstroms at a reaction temperature of about 1050° C., the total time of the reaction (I) takes about 20 seconds or more.

H₂+N₂O→H₂O+NO*+O*+OH*+other species (I)

While, by the conventional ISSG process to form an ultra-thin gate oxide layer with a thickness about 15 angstroms, the total reaction time only takes 10 seconds. For forming an ultra-thin gate dielectric layer (≦15 angstroms), the reaction time of the present N₂O-ISSG process is slower than the conventional ISSG process. Therefore, the present N₂O-ISSG process provides a better thickness control than the conventional ISSG process for forming the ultra-thin gate dielectric layer.

Referring to FIG. 3, the oxynitride layer 104 formed by the present N₂O-ISSG process has a nitrogen content about 1˜5 atomic %. Therefore, the oxynitride layer 104 has a nitrogen content in the surface region and the interface region of the silicon substrate 101 about 15 atomic %. The nitrogen atoms contained in the surface region and the interface region of the oxynitride layer 104 act as a barrier to inhibit boron penetration from the doped polysilicon gate and the hot electrons injecting into the ultra-thin gate oxide due to the hot carrier effect. The 1˜5 atomic % nitrogen content in the oxynitride layer 104 also increases the dielectric constant of the oxynitride layer 104, so as to improve the MOS transistor device performance of which the ultra-thin oxynitride layer is used as the gate dielectric layer.

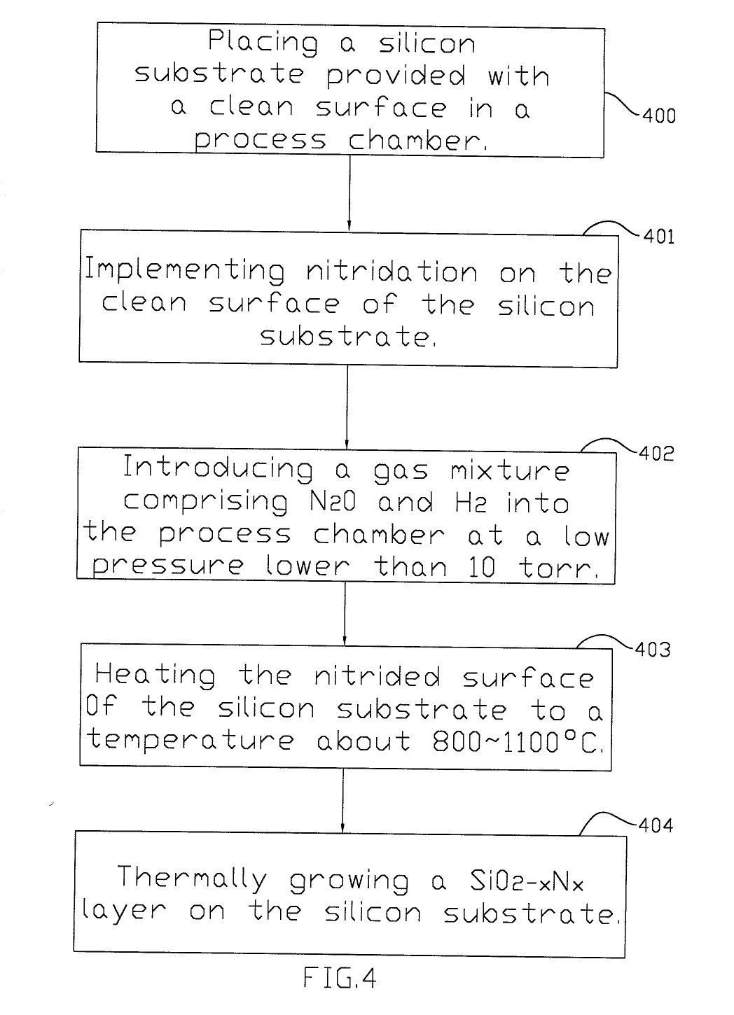

In another preferred embodiment, a nitridation process is implemented on the surface of the silicon substrate 101 prior to the N₂O-ISSG process, whose process flow is shown in FIG. 4. In step 400, the silicon substrate 101 provided with a clean surface, is placed in the rapid thermal process chamber 100. In step 401, implementing nitridation on the clean surface of the silicon substrate 101 to form a nitrogen-rich layer on the surface. The nitridation can be performed by way of the rapid thermal process utilizing NH₃ as the reaction gas. Besides, the nitridation can be performed by way of remote plasma nitridation process using H₂/N₂ as the reaction gases at the temperature of about 500˜800° C. and the pressure about 1˜3 torr. In step 402, a gas mixture comprising N₂O and H₂ is introduced into the rapid thermal process chamber 100 at a low pressure lower than 10 torr. The gas mixture consists essentially of N₂O and has a H₂ gas ratio less than 1%. In step 403, heating the nitrided surface of the silicon substrate 101 to a temperature about 800˜1100° C. In step 404, the heated nitrided surface of the silicon substrate 101 initiates the reaction (1) as mentioned above occur to produce atomic oxygen (O) and nitric oxide (NO) radical at the nitrided surface of the silicon substrate 101. Then, an oxynitride (SiO₂₋ₓNₓ) layer is formed on the nitrided surface of the silicon substrate 101.

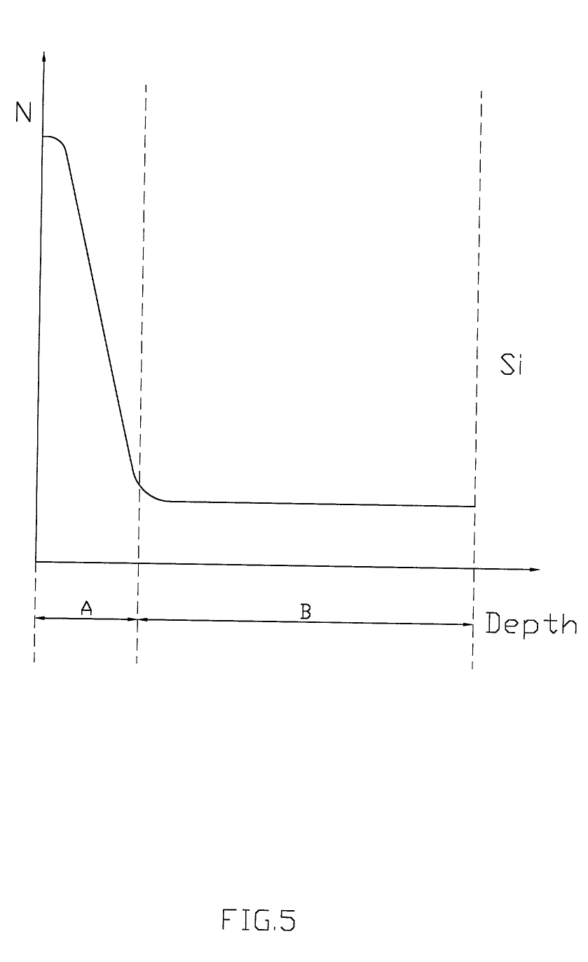

In this alternate embodiment, the nitridation is implemented on the surface of the silicon substrate 101 prior to the N₂O-ISSG process. The nitridation make a nitrogen-rich layer firstly formed on the surface of the silicon substrate 101. Then, during the N₂O-ISSG process, atomic oxygen (O) and nitric oxide (NO) radicals diffuse into the silicon substrate 101 through the nitrogen-rich layer to form an oxynitride layer between the nitrogen-rich layer and the silicon substrate 101. Therefore, as shown in FIG. 5, the nitrogen concentration in the surface region A formed of the nitrogen-rich layer is much higher than the region B formed of the oxynitride layer. Since the nitrogen-rich layer is formed on the top surface of the silicon substrate 101, boron penetration could be more efficiently prevented. The total dielectric constant of the gate dielectric layer formed of the nitrogen-rich layer and the oxynitride layer is also increased to improve performance of the MOS device using this gate dielectric layer.

In accordance with the foregoing, the present N₂O in-situ steam generation process could provide ultra-thin gate dielectric layer (≦15 angstroms), such as ultra-thin oxynitride layer, with good thickness control. The ultra-thin gate dielectric layer could efficiently inhibit quantum effect, such as boron penetration and hot carrier effect. The present N₂O-ISSG process also enable higher temperature control, above 1000° C. Therefore, the present N₂O-ISSG process provides a wider process window than the conventional ISSG.

The preferred embodiments are only used to illustrate the present invention, not intended to limit the scope thereof. Many modifications of the preferred embodiments can be made without departing from the spirit of the present invention.

What is claimed is:

1. An in-situ steam generation (ISSG) process for nitrided oxide, comprising:
heating a surface of a silicon substrate to a predetermined temperature and exposing the heated surface of said silicon substrate to a gas mixture, said gas mixture being introduced in a chamber and comprising N₂O and H₂, thereby causing growth of a silicon dioxide layer on the heated surface of said silicon substrate, said silicon dioxide layer containing nitrogen.

2. The process of claim 1, wherein said gas mixture consists essentially of N₂O.

3. The process of claim 2, wherein said gas mixture contains H₂ with a gas ratio less than 1%.

4. The process of claim 1, wherein said gas mixture is introduced into the chamber at a pressure lower than 10 torr.

5. The process of claim 1, wherein said predetermined temperature is about 800 to 1100° C.

6. The process of claim 1, wherein said silicon dioxide layer has a thickness of less than 15 angstroms.

7. The process of claim 1, wherein the content of nitrogen in said silicon dioxide layer is about 1˜5 atomic %.

8. The process of claim 1, wherein the content of nitrogen in the surface of said silicon dioxide layer is about 1˜5 atomic %.

9. The process of claim 1, wherein the content of nitrogen in the interface between said silicon dioxide layer and said silicon substrate is about 1˜5 atomic %.

10. The process of claim 1, further comprising implementing nitridation on the surface of said silicon substrate prior to said in-situ steam generation process.

11. The process of claim 10, wherein said nitridation is performed by way of rapid thermal process using NH₃ as the reaction gas.

12. The process of claim 10, wherein said nitridation is performed by way of remote plasma nitridation using H₂/N₂ as reaction gases at a temperature of about 500˜800° C. and a pressure of about 1˜3 torr.

13. An in-situ steam generation (ISSG) process for forming a nitrided silicon dioxide layer on a silicon substrate, comprising:
placing said silicon substrate in a process chamber;
introducing a gas mixture comprising N₂O and H₂ into the process chamber; and
heating the surface of said silicon substrate to a predetermined temperature to cause growth of said nitrided silicon dioxide layer on the heated surface of said silicon substrate.

14. The process of claim 13, wherein said gas mixture consists essentially of N₂O.

15. The process of claim 14, wherein said gas mixture contains H₂ with a gas ratio less than 1%.

16. The process of claim 13, wherein said gas mixture is introduced into the process chamber at a pressure lower than 10 torr.

17. The process of claim 13, wherein said predetermined temperature is about 800˜1100° C.

18. The process of claim 13, wherein said nitrided silicon dioxide layer has a thickness of less than 15 angstroms.

19. The process of claim 13, wherein said nitrided silicon dioxide layer has nitrogen in said silicon dioxide layer with a gas ratio about 1˜5 atomic %.

20. The process of claim 13, wherein said nitrided silicon dioxide layer has nitrogen in the surface of said silicon dioxide layer with a content about 1˜5 atomic %.

21. The process of claim 13, wherein said nitrided silicon dioxide layer has nitrogen in the interface between said silicon dioxide layer and said silicon substrate with a content about 1˜5 atomic %.

22. The process of claim 13, further comprising implementing a nitridation on the surface of said silicon substrate prior to introducing said gas mixture into the process chamber.

23. The process of claim 22, wherein said nitridation is performed by way of rapid thermal process using NH₃ as the reaction gas.

24. The process of claim 22, wherein said nitridation is performed by way of remote plasma nitridation using H₂/N₂ as reaction gases at a temperature of about 500˜800° C. and a pressure of about 1˜3 torr.
